(19) United States
(12) Patent Application Publication
(10) Pub. No.: US 2026/0194570 A1
(43) Pub. Date: Jul. 9, 2026

(54) BASE CURRENT COMPENSATION FOR PMU OUTPUT STAGE

(71) Applicant: Analog Devices, Inc., Wilmington, MA (US)

(72) Inventors: Amit Kumar Singh, Woburn, MA (US); Christopher C. McQuilkin, Hollis, NH (US)

(21) Appl. No.: 19/011,234

(22) Filed: Jan. 6, 2025

(51) Int. Cl. G01R 31/28

(52) U.S. Cl. CPC G01R 31/2834

(57) ABSTRACT

A test equipment system can include an output stage configured to provide a DUT signal to a device under test in response to a force control signal. The output stage can include first and second output transistors and a bias circuit providing bias current to the first output transistor. The system can include a sense device configured to sense current information about the DUT signal, and a control circuit that generates a supplement current based on the sensed current information. The supplement current can be provided to one of the output transistors. In an example, the sense device comprises a scaled replica transistor of the first output transistor. The magnitude of the supplement current can be continuously updated based on changes in the DUT signal.

### BACKGROUND

A test system for electronic device testing can include a pin driver circuit that provides a voltage test pulse to a device under test (DUT). In response, the test system can be configured to measure a response from a DUT, such as to determine whether the DUT meets one or more specified operating parameters. A test system can optionally include multiple different classes of driver circuits to provide circuit test signals having different amplitude or timing characteristics. In an example, the test system is configured to measure a response from a DUT using an active load and a comparator circuit to sense transitions at a DUT pin.

A system for testing digital integrated circuits (ICs) can include a per-pin parametric measurement unit (PPMU or PMU). A PMU can be configured to operate in different modes to provide, or force, a current or voltage signal to a DUT, and to receive, or measure, a corresponding response from the DUT. The operating modes can include, for example, a force voltage measure current (FVMI) mode, a force current measure voltage (FIMV) mode, a force current measure current (FIMI) mode, a force voltage measure voltage (FVMV) mode, or a force nothing measure voltage (FNMV) mode. A PMU can have various force and sense operating ranges that can be modified using, for example, external amplifiers or resistors.

In an example, a test system can include a driver circuit configured to provide multiple voltage levels (e.g., Vhigh, Vlow and Vterm) to a DUT. The DUT can exhibit bidirectional (I/O) capability in that it can both source and receive stimulus. The driver circuit's Vhigh and Vlow levels serve to stimulate a DUT while in its “input” state, and Vterm acts as a termination for the DUT in its “output” state. The process of switching between Vhigh, Vlow, and Vterm can be conceptualized as a collection of three switches, with one terminal of each switch connected to either Vhigh, Vlow, or Vterm, and the other terminal connected to a 50 ohm resistor, which is then connected to the DUT node. Transitions between the three levels can be realized by opening and closing the appropriate switches, such as with one switch closed at any given time. A test system can include other functions, such as an active load and high-speed comparator. The active load can provide the DUT with a bi-directional current source load, and the comparator can serve as a DUT waveform digitizer.

### BRIEF SUMMARY

The present inventors have recognized, among other things, that a problem to be solved includes providing a packaged automated test system configured to provide driver, comparator, active load, and per-pin parametric measurement functions. The inventors have recognized the problem includes accommodating the speed and accuracy requirements of, for example, the driver, comparator, and active load circuitry using integrated device structures that occupy minimal die area, while minimizing loading effects at an interface with a device under test (DUT), and while maximizing a functional test range of the system. The problem can include providing a system that is relatively small, inexpensive to produce, consumes less power than traditional systems, or provides higher fidelity performance relative to traditional systems.

The present inventors have further recognized that the problem can include accommodating the competing requirements of high-speed operation and DC/low-speed parametric measurements in an integrated circuit device. Specifically, the problem can include managing the poor beta characteristics of PNP transistors that result from using a fabrication process that optimizes for higher-speed devices, and maintaining efficient power consumption across the full operating range of the parametric measurement unit or PMU. The problem can be particularly pronounced when a PMU is used to source or sink high DUT currents.

In an example, a solution to these and other problems can include or use a base current compensation technique that uses a scaled replica circuit to sense DUT current, and a feedback network to provide proportional base current compensation. In an example, the solution can include or use a proxy “scaled-down” replica device or devices, such as PNP or NPN transistors, collector resistors, and current mirrors, to infer a PMU output stage current and maintain substantially the same operating conditions at the replica and output stage devices. This approach allows a compensation circuit to infer output stage current and generate a base current that matches the output stage base current. This matched (base) current can then be applied to the PMU output stage to make the output stage substantially insensitive to output stage current variations. For example, large DUT currents can produce large matched (base) current, while small DUT currents can produce small matched (base) current. In this way, the circuit is optimized thereby avoiding unnecessary power consumption in low-current or quiescent operating conditions. The solution is effective in systems that use transistors with low beta and helps maintain operating power efficiency across the full DUT current range of the parametric measurement unit.

This summary is intended to provide an overview of subject matter of the present patent application. It is not intended to provide an exclusive or exhaustive explanation of the invention. The detailed description is included to provide further information about the present patent application.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1 illustrates generally an example of a test system topology including multiple driver circuits.

FIG. 2 illustrates generally an example of a first output stage for a test system that includes a class A buffer circuit coupled to a class AB output stage.

FIG. 3 illustrates generally an example of a second output stage for a test system that includes a class A buffer circuit coupled to a class AB output stage.

FIG. 4 illustrates generally an example of a first method for operating an automated test equipment (ATE) system in accordance with one embodiment.

### DETAILED DESCRIPTION

A test system, such as a force-sense test system for use with automated test equipment (ATE), can be configured to provide a voltage or current stimulus to a device under test (DUT) at a specified time, and optionally can measure a response from the DUT. The test system can be configured to provide high fidelity output signal pulses over a relatively large output signal magnitude range to accommodate different tests and different types of devices under test.

In an example, a force-sense system, or force-sense measurement device, can include a pin driver architecture that can provide high fidelity stimulus with minimal overshoot which enhances pulse edge placement accuracy. The test system can include a single-package ATE solution that can include, among other things, a driver circuit, comparator circuit, and active load circuit, and a per-pin parametric measurement unit (PPMU or PMU), sometimes referred to herein as a PMU circuit. The driver, comparator, and active load circuits are referred to herein collectively as a DCL or DCL circuit. In an example, the PMU circuit can be configured for use in high precision, relatively lower frequency, lower bandwidth, and higher amplitude stimulus testing and the DCL circuit can be configured for use in relatively higher frequency and higher bandwidth stimulus testing. Control circuitry can be provided to select a particular force stimulus, such as from the PMU circuit or the DCL circuit, for use in a particular test depending on parameters or requirements of the test. In some examples, operation of the PMU circuit and the DCL circuit can be mutually exclusive such that only one of the circuits interfaces with the DUT at any given time. Various other control circuitry can be provided, such as including digital-to-analog converters (DACs) with on-chip calibration registers to enable use at different DC operating levels.

The present inventors have recognized that implementing both high-speed driver/receiver circuits and parametric measurement functions on a common integrated circuit presents significant technical challenges. In particular, the high-speed process technology used for the driver and receiver circuits can produce transistors with poor beta characteristics in the PMU output stage. When handling high DUT currents, these poor beta characteristics cause the base current requirements of the output transistors to become large, exceeding the current that prior circuit stages can effectively provide without compromising power efficiency. Simply increasing the bias current to handle these high base current requirements produces excessive power dissipation in the output stage during low or zero DUT current conditions.

A solution to these problems includes a compensation circuit that uses a scaled replica transistor to sense DUT current and provide proportional base current compensation at the PMU output stage transistors. The compensation circuit includes a differential amplifier that senses collector voltages between a main output transistor and a scaled-down sense transistor (e.g., the replica transistor), with matched collector resistors maintaining equal current densities and voltages between the replica devices and the output stage devices. A current mirror can provide a supplement base current that automatically scales with DUT current demands, thus increasing drive capability during high DUT current demand while scaling down at low DUT currents to maintain power efficiency. This approach enables integration of a PMU that is optimized for power efficiency alongside high-speed driver and receiver circuits on the same die.

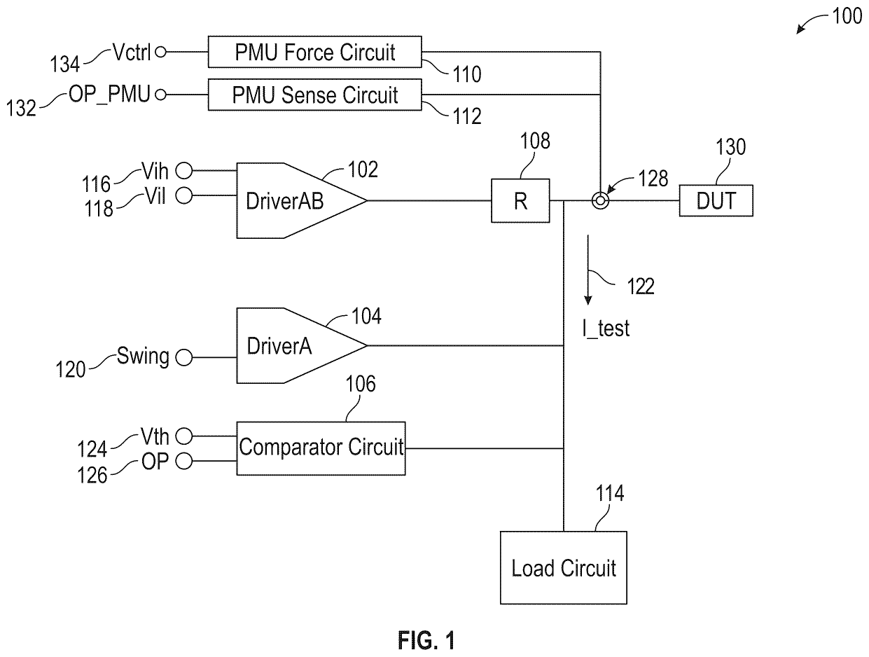

FIG. 1 illustrates generally a first example 100 of a force-sense test system topology including a PMU circuit and a DCL circuit. In the first example 100, the PMU circuit includes a PMU force circuit 110 and a PMU sense circuit 112 coupled to a DUT pin 128, and the DUT pin 128 can be coupled to a DUT 130. In the first example 100, the DCL circuit includes a first DriverAB 102 that can include a class AB driver circuit (e.g., a class AB output stage), and a first DriverA 104 that can include a class A driver circuit (e.g., a class A output stage). The DCL circuit can include a comparator circuit 106 and a first load circuit 114, such as can include an active load or other loading device. The first example 100 can further include an output element such as a first resistor 108 that can be configured to provide a specified output or load impedance. In an example, the test system is configured to source or sink a first current signal 122, i_test, at the DUT pin 128 that is coupled to the DUT 130. The force-sense test system can be configured to concurrently perform voltage and current measurements on signals received from, or provided to, the DUT 130, such as while applying a voltage or current excitation stimulus to the DUT 130.

In an example, the PMU force circuit 110 can be configured to provide a stimulus using a digitally-configurable amplifier circuit and one or more output buffers. The PMU force circuit 110 can receive a force control signal, such as a digital PMU control signal 134 Vctrl, and in response, the PMU force circuit 110 can provide a drive signal at the DUT pin 128. The PMU sense circuit 112 can be configured to receive voltage or current information from the DUT 130, such as using a resistive network. The PMU circuit can include a feedback network to receive test control signals, and the voltage or current information from the DUT 130, to thereby control operation of the PMU force circuit 110. In an example, the PMU sense circuit 112 can be configured to provide a PMU output signal 132 OP_PMU, such as to an external system controller.

In an example, the first DriverAB 102 can be configured to produce a voltage stimulus signal by selecting between parallel-connected diode bridges with each bridge driven by a unique, dedicated DC voltage level. In the first example 100 of FIG. 1, DUT control signals or DC voltages Vih 116 and Vil 118 drive diode bridges in the first DriverAB 102. The switching stage can be followed by a voltage buffering stage that can provide power gain, such as can be used to produce large currents to serve a 50 ohm DUT environment.

In contrast with the first DriverAB 102, the first DriverA 104 can be configured to produce transitions at the DUT 130 using a relatively large current switch stage that can be coupled directly to the DUT 130. A current switching stage in the first DriverA 104 can alternately switch current into and out of the DUT 130 in response to a DUT control signal Swing 120, such as can be a voltage control signal. The first DriverA 104 can provide high speed operation, for example, because it may be unburdened by the class AB voltage buffering stage with its attendant bandwidth limitations and other performance limitations.

In an example, the first DriverA 104 can be configured to provide a relatively low amplitude signal at the DUT 130. For example, the first DriverA 104 can provide a signal having about a 2 volt swing. The first DriverAB 102 can be configured to provide a relatively high amplitude signal at the DUT 130, for example, −1.5 to +7 volts. The first DriverA 104 generally operates at a higher switching speed or bandwidth than the first DriverAB 102. In an example, the first DriverAB 102 can be configured to absorb switching currents from the first DriverA 104. That is, the first DriverAB 102 can serve as a buffer that the first DriverA 104 can source current into, such as through the first resistor 108.

One or more of the PMU force circuit 110, the first DriverAB 102 and the first DriverA 104 can be selected to fulfill disparate DUT test requirements that may not otherwise be fulfilled by a single circuit. For example, while each of the driver circuits can provide DUT signals or waveforms, the first DriverAB 102 can be configured to provide large amplitude, low bandwidth stimulus signals, and the first DriverA 104 can be configured to provide low amplitude, high bandwidth stimulus signals. The PMU force circuit 110, for example, can be configured to provide precise high amplitude current and voltage signals such as at DC or low bandwidth levels.

In an example, the PMU circuit and the DCL circuit include respective independent enable control pins. The independent enable controls can help facilitate independent operation of the different circuits. For example, the first DriverAB 102 can serve as a low speed, high voltage stimulus source, or can serve as a static, non-transitioning buffer to absorb switching currents from the first DriverA 104, such as depending on a state of a control signal at the enable control pin of the first DriverAB 102. In an example, the first DriverAB 102 and the first DriverA 104 can be disabled when the PMU circuit is active, and the PMU circuit can be disabled when one of the first DriverAB 102 and the first DriverA 104 is active.

FIG. 1 includes the comparator circuit 106. The comparator circuit 106 can include a multiple-stage comparator that is configured to receive signals from the DUT 130, such as via the DUT pin 128. The comparator circuit 106 can compare the received signals to a comparator reference signal 124 and, in response, provide a differential comparator output signal 126. For example, the comparator circuit 106 can receive a voltage response signal from the DUT 130 and compare an amplitude of the voltage response signal to an amplitude of the comparator reference signal 124. The comparator circuit 106 can provide information about the amplitude relationship using the differential comparator output signal 126, such as can include a digital signal or logic output signal.

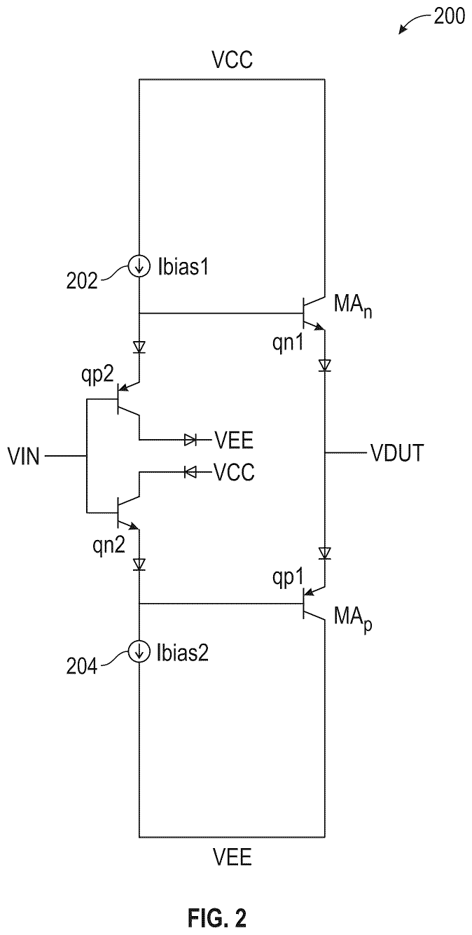

FIG. 2 illustrates generally an example of a first output stage 200 buffer of a PMU force circuit. The circuit includes a positive supply node VCC and a negative supply node or reference node VEE.

The buffer circuit includes a first bias current source 202 coupled to VCC, and transistors qp2 and qn2 arranged in a source follower topology. An input node VIN is coupled to the base nodes of transistors qp2 and qn2. A second bias current source 204 is coupled between qn2 and VEE. In an example, the first bias current source 202 and second bias current source 204 are constant current sources that provide respective fixed (i.e., limited) currents Ibias1 and Ibias2 to bias the transistors qp2 and qn2.

The buffer circuit can receive VIN as a DUT control signal and, in response, provide an output signal to an output stage. In the example of FIG. 2, the outputs of the buffer circuit are at the emitter terminals of the transistors qp2 and qn2. These outputs are coupled to respective base terminals of transistors in the class AB output stage. The output stage can provide a DUT drive signal at a DUT interface node VDUT and at arbitrarily high (or low) current.

The output stage includes an NPN transistor qn1 and a PNP transistor qp1 arranged in a push-pull configuration. The output transistors qn1 and qp1 can each comprise multiple parallel-coupled instances of BJT devices to handle high current operation. In an example, transistor qn1 comprises M parallel-coupled NPN devices and transistor qp1 comprises M parallel-coupled PNP devices. In this case, an effective area of transistor qn1 is represented as M*An, and an effective area of transistor qp1 is represented as M*Ap. The output or DUT interface node VDUT is coupled between the emitter terminals of the output transistors qn1 and qp1. Various protection diodes can be provided throughout the first output stage 200 as illustrated.

The present inventors have recognized that the first output stage 200 faces limitations when handling high DUT currents. In particular, if PNP devices such as the output transistor qp1 are implemented using bipolar device process technologies that are selected to help realize higher speed operation, then the devices may have less optimal beta characteristics. A device beta characteristic refers to the ratio of collector current to base current in a BJT device. In operation of an ATE system that comprises the first output stage 200, base current requirements in the output stage can become high and may exceed what the prior stage (e.g., the transistors qn2 or qp2) can effectively provide. The inventors have recognized that increasing the bias current Ibias2 from the second bias current source 204 to handle high base current requirements can lead to high power dissipation in the output stage, such as when the DUT current is low or zero, as the increased bias current pulls the base voltage of transistor qp1 lower and creates unnecessary standing current through the output transistors of the output stage. This can inhibit the output stage from efficiently handling high DUT currents while maintaining low power consumption during quiescent operation.

In other words, high DUT current demand is serviced by the second bias current source 204, however, the second bias current source 204 also provides biasing for the transistor qn2 in the class A buffer circuit. If the second bias current source 204 is configured to accommodate high current DUT signals, then the first output stage 200 may unnecessarily consume or dissipate power when DUT current demands are low.

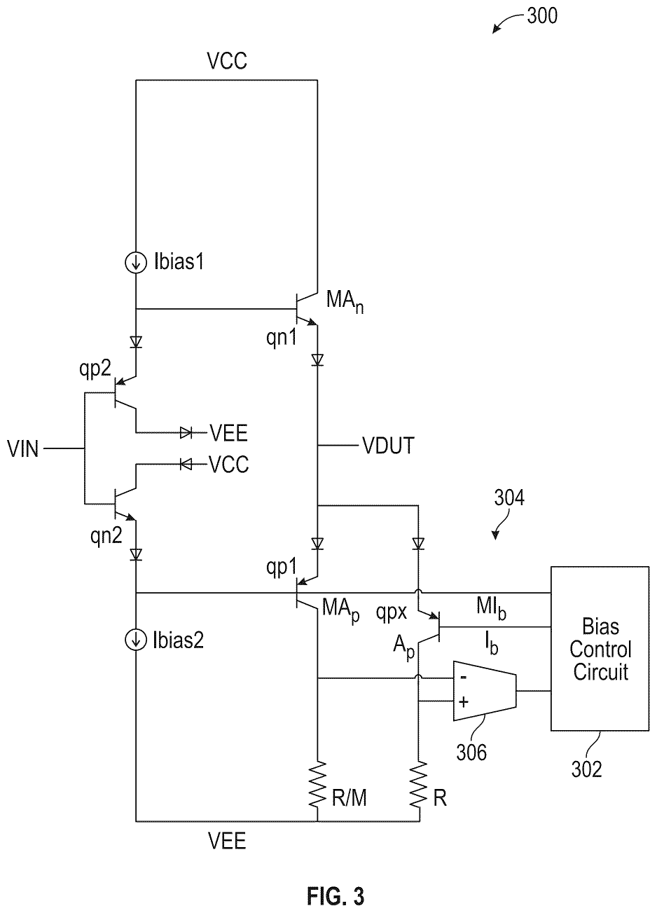

FIG. 3 illustrates generally an example of a second output stage 300 for a test system that includes a class A buffer circuit coupled to an output stage. In an example, the second output stage 300 can address some of the limitations of the first output stage 200 discussed above. The example of the second output stage 300 shares some architecture with the first output stage 200, including the source follower transistors qp2 and qn2, and the push-pull output transistors qn1 and qp1.

The second output stage 300 includes a feedback network 304 that can be used to help address the output transistor base current issues discussed above. That is, the feedback network 304 can be used to ensure the current provided by qn2 is relatively low even during times of high DUT current demand, and to minimize power dissipation during times of low DUT current demand. In an example, the feedback network 304 includes a sense transistor qpx that can be a scaled replica of the output transistor qp1. For example, the output transistor qp1 can comprise M parallel-coupled PNP transistors, and the sense transistor qpx can be scaled down by a factor of M relative to qp1. Other scaling factors can similarly be used.

In an example, the output transistor qp1 of the output stage is coupled to a collector resistor having resistance R/M. In an example, the sense transistor qpx in the feedback network 304 is coupled to a collector resistor with resistance R. The resistance values of the collector resistors are scaled proportionally (e.g., by the same factor of M) to help maintain equal current density characteristics between the output transistor qp1 and the sense transistor qpx when their collector voltages are matched.

The feedback network 304 can include an amplifier circuit 306 (e.g., a differential amplifier circuit) and a bias control circuit 302. The amplifier circuit 306 can be configured to sense respective voltages at the collector terminals of the output transistor qp1 and the sense transistor qpx. The amplifier circuit 306 provides an output or control signal to the bias control circuit 302. The bias control circuit 302 generates a first current signal Ib that is provided to the base node of the sense transistor qpx, and a supplement current MIb that is provided to the base node of the output transistor qp1. The feedback network 304 is thus configured to equalize the collector voltages of the output transistor qp1 and the sense transistor qpx.

The bias control circuit 302 optionally includes a current mirror circuit that is configured to provide the supplement current MIb as a scaled-up version of the first current signal Ib. The scaling ratio of the current mirror circuit can match the M:1 physical scaling ratio between the output transistor qp1 and the sense transistor qpx.

In an example, the feedback network 304 can be used to automatically cancel the base current of the output transistor qp1 based on DUT current demands. When DUT current is high, the sense transistor qpx detects the relative magnitude of the DUT current and the feedback network 304 increases the base current of the sense transistor qpx and hence the base current of the output transistor qp1 proportionally. Conversely, when DUT current is low, the base current of the output transistor qp1 scales down, maintaining power efficiency. The matched scaling between transistor sizes, resistor values, and current mirror ratio ensures accurate tracking across process variations and operating conditions.

In the example of the second output stage 300, the buffer circuit with source follower transistors qp2 and qn2 provides input signal buffering, while the output stage with output transistors qn1 and qp1 handles the high-current output drive requirements. The feedback network 304 ensures that the transistor qn2 has adequate current available to accommodate high DUT current, and thus high transistor qp2 base current. Together, these components form a parametric measurement unit (PMU) output stage configured to handle a wide range of DUT currents, even when the transistors that comprise the PMU have less than optimal beta characteristics.

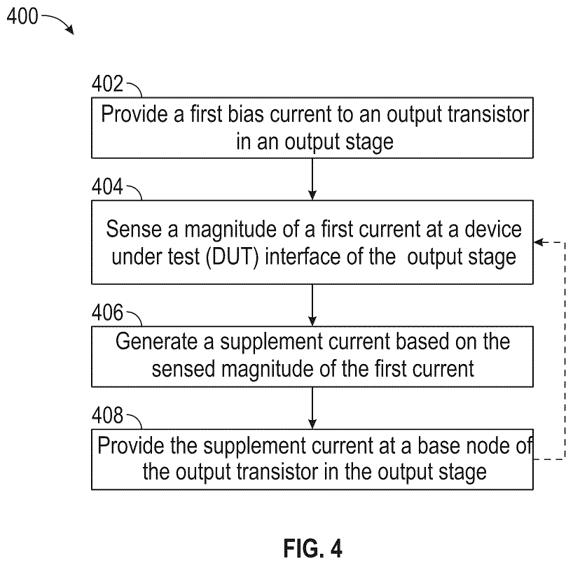

FIG. 4 illustrates generally an example of a first method 400 for automatically adjusting drive characteristics of output buffer circuitry based on DUT current demands. Although the example of the first method 400 depicts a particular sequence of operations, the sequence may be altered without departing from the scope of the present disclosure. For example, some of the operations depicted may be performed in parallel or in a different sequence that does not materially affect the function of the first method 400. In other examples, different components of an example device or system that implements the first method 400 may perform functions at substantially the same time or in a specific sequence.

At operation 402, the first method 400 includes providing a first bias current to an output transistor in an output stage. The output transistor can include a PNP transistor comprising M parallel-coupled devices.

At operation 404, the first method 400 includes sensing a magnitude of a first current at a device under test (DUT) interface of the output stage. In an example, operation 404 can include or use a PNP sense transistor that is a scaled replica of the PNP output transistor. For example, the sense transistor can have a physical size that is scaled down by a factor of M relative to a physical size of the output transistor. In an example, operation 404 includes sensing voltage characteristics from each of the output transistor and the sense transistor. Respective collector resistors can be provided, and resistance characteristics of the resistors can be proportionally scaled to help maintain equal current density characteristics in the transistors.

At operation 406, the first method 400 includes generating a supplement current based on the sensed magnitude of the first current. In an example, a differential amplifier circuit senses respective voltages at the collector terminals of the output transistor and sense transistor and, in response, provides a control signal with information about the voltage difference. A bias control circuit can receive the voltage difference information and, in response, provide a first current signal at a base node of the sense transistor, and provide a supplement current at a base node of the output transistor. The supplement current can be proportional to the first current signal or to the voltage difference. In an example, the bias control circuit includes a current mirror circuit that is configured to generate the supplement current as a scaled-up version of the first current signal.

At operation 408, the first method 400 includes providing the supplement current at the base node of the output transistor in the output stage. The supplement current can be scaled relative to the first current signal in a same ratio as the output transistor is physically scaled relative to the sense transistor.

In an example, following operation 408, the first method 400 can include returning to operation 404 to again sense a magnitude of a current at the DUT interface. Changes in the current magnitude or DUT current demand can cause corresponding changes in the supplement current provided to the output transistor. That is, a magnitude of the supplement current can be updated or changed in correspondence with changes in the DUT current. This feedback operation helps maintain matched operating conditions between the output transistor and sense transistor across varying load conditions, and helps ensure that high and low DUT current conditions are accommodated.

While the above examples are generally directed to compensating base current for the PNP output transistor qp1, a similar compensation approach can be used for the NPN output transistor qn1. The NPN compensation technique can include, for example, a scaled-down replica of qn1 to sense collector current, matched collector resistors to maintain equal current densities, and a feedback network with differential amplifier and current mirror to provide proportional base current compensation. However, since NPN transistors in the high-speed process typically have better beta characteristics than PNP devices, the base current compensation may be less critical for the NPN side. In the example implementation shown in FIG. 3, only PNP compensation is provided to minimize die area while addressing the more significant beta limitations of the PNP devices.

While the discussion herein focuses generally on bipolar transistor implementations, the compensation techniques discussed herein can be similarly implemented using field-effect transistors (FETs) or using bipolar and FET devices together. For example, in a FET-based implementation, an output stage can use complementary MOSFET devices with a scaled replica FET sensing the DUT current, and a feedback network can be configured to equalize operating conditions between the main output and sense devices to achieve efficient power scaling. In an example, a FET-based implementation can be made more power efficient by making the second bias current source 204 dependent on the sensed DUT current.

Various aspects of the present disclosure, presented below as numerically identified Examples, can help provide a solution to the test system-related problems identified herein.

Example 1 is a test equipment system for providing signals to, or receiving signals from, a device under test (DUT), the system comprising: a first output stage configured to provide a DUT signal to the DUT in response to a force control signal, the first output stage comprising first and second output transistors; a bias circuit configured to provide a bias current at a base node of the first output transistor; a sense device configured to sense current information about a current magnitude of the DUT signal; and a control circuit configured to generate a supplement current based on the sensed current information and provide the supplement current at the base node of the first output transistor.

In Example 2, the subject matter of Example 1 optionally includes the sense device is a scaled replica transistor of the first output transistor.

In Example 3, the subject matter of Example 2 optionally includes the first output transistor comprises M parallel-coupled PNP transistors, the second output transistor comprises an NPN transistor, and the sense device comprises at least one PNP transistor.

In Example 4, the subject matter of one or more of Examples 2-3 optionally includes a physical size of the scaled replica transistor is scaled down by a factor of M relative to a physical size of the first output transistor.

In Example 5, the subject matter of Example 4 optionally includes a first sense resistor coupled to a collector terminal of the first output transistor and a second sense resistor coupled to a collector terminal of the scaled replica transistor, and a resistance of the first sense resistor is scaled down by the factor of M relative to a resistance of the second sense resistor.

In Example 6, the subject matter of one or more of Examples 2-5 optionally includes the control circuit comprises a differential amplifier circuit configured to sense respective voltages at each of the first output transistor and the scaled replica transistor and, in response, provide a first current signal at a base node of the sense device.

In Example 7, the subject matter of Example 6 optionally includes the control circuit comprises a current mirror configured to provide the supplement current as a scaled-up version of the first current signal.

In Example 8, the subject matter of one or more of Examples 1-7 optionally includes a class A buffer stage configured to receive a DUT control signal and, in response, provide an output signal to an input node of the first output stage, wherein the first output stage comprises a class AB output stage.

In Example 9, the subject matter of Example 8 optionally includes the class A buffer stage comprises a source follower circuit coupled to the bias circuit.

In Example 10, the subject matter of one or more of Examples 8-9 optionally includes the class A buffer stage and class AB output stage comprise portions of a per-pin parametric measurement unit (PPMU or PMU) of the test equipment system.

Example 11 is a compensation circuit for an output stage of a pin driver system, the compensation circuit comprising: a replica transistor comprising a physically scaled-down replica of a first transistor in an output stage of the pin driver system; a control circuit configured to provide a first drive current at a base node of the replica transistor based on information about a voltage difference between the replica transistor and the first transistor in the output stage; and a current source configured to provide a supplement current at a base node of the first transistor in the output stage, wherein the supplement current is scaled relative to the first drive current in a same ratio as the first transistor in the output stage is physically scaled relative to the replica transistor.

In Example 12, the subject matter of Example 11 optionally includes the first transistor comprises M parallel-coupled PNP transistors and the replica transistor comprises at least one but fewer than M PNP transistors.

In Example 13, the subject matter of Example 12 optionally includes the control circuit comprises a differential amplifier configured to receive respective voltage signals from collector terminals of the replica transistor and the first transistor in the output stage and the current source comprises a current mirror circuit.

Example 14 is a method for operating an automated test equipment (ATE) system, the method comprising: sensing a magnitude of a first current at a device under test (DUT) interface of a DUT driver output stage; generating a supplement current based on the sensed magnitude of the first current; providing the supplement current at a base node of an output transistor in the output stage.

In Example 15, the subject matter of Example 14 optionally includes the output stage of the ATE system comprises an output stage with a first NPN transistor coupled to a first PNP transistor, and sensing the magnitude of the first current includes using a second PNP transistor that is a scaled replica of the first PNP transistor.

In Example 16, the subject matter of Example 15 optionally includes receiving information about a first collector voltage of the first PNP transistor; receiving information about a second collector voltage of the second PNP transistor; using a bias control circuit, providing the supplement current to the base node of the first PNP transistor and providing a second bias current to a base node of the second PNP transistor to equalize the first and second collector voltages.

In Example 17, the subject matter of Example 16 optionally includes providing the second bias current to a current mirror circuit and generating the supplement current as a scaled-up version of the second bias current using the current mirror circuit.

In Example 18, the subject matter of Examples 14-17 optionally includes biasing the output transistor in the output stage and biasing a buffer circuit using a first current source, wherein an output of the buffer circuit is coupled to an input of the output stage.

In Example 19, the subject matter of Examples 14-18 optionally includes using a feedback network to equalize current density characteristics of the output transistor and a sense transistor; wherein sensing the magnitude of the first current includes using the sense transistor, and the sense transistor is a scaled replica of the output transistor.

In Example 20, the subject matter of Examples 14-19 optionally includes sensing a change in magnitude of the first current at the DUT interface of the output stage; generating an updated supplement current based on the sensed change in magnitude of the first current; and providing the updated supplement current at the base node of an output transistor in the output stage.

Each of these non-limiting Examples can stand on its own, or can be combined in various permutations or combinations with one or more of the other Examples or features discussed elsewhere herein.

This detailed description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventors also contemplate examples in which only those elements shown or described are provided. The present inventors contemplate examples using any combination or permutation of those elements shown or described (or one or more aspects thereof), either with respect to a particular example (or one or more aspects thereof), or with respect to other examples (or one or more aspects thereof) shown or described herein.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.”

In the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

Method examples described herein can be machine or computer-implemented at least in part. Some examples can include a computer-readable medium or machine-readable medium encoded with instructions operable to configure an electronic device to perform methods or circuit operations or circuit configuration instructions as described in the above examples. An implementation of such methods can include code, such as microcode, assembly language code, a higher-level language code, or the like. Such code can include computer readable instructions for performing various methods. The code may form portions of computer program products. Further, in an example, the code can be tangibly stored on one or more volatile, non-transitory, or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMs), read only memories (ROMs), and the like.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description as examples or embodiments, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

What is claimed is:

1. A test equipment system for providing signals to, or receiving signals from, a device under test (DUT), the system comprising:
a first output stage configured to provide a DUT signal to the DUT in response to a force control signal, the first output stage comprising first and second output transistors;
a bias circuit configured to provide a bias current at a base node of the first output transistor;
a sense device configured to sense current information about a current magnitude of the DUT signal; and
a control circuit configured to generate a supplement current based on the sensed current information and provide the supplement current at the base node of the first output transistor.

2. The test equipment system of claim 1, wherein the sense device comprises a scaled replica transistor of the first output transistor.

3. The test equipment system of claim 2, wherein the first output transistor comprises M parallel-coupled PNP transistors, the second output transistor comprises an NPN transistor, and the sense device comprises at least one PNP transistor.

4. The test equipment system of claim 2, wherein a physical size of the scaled replica transistor is scaled down by a factor of M relative to a physical size of the first output transistor.

5. The test equipment system of claim 4, comprising a first sense resistor coupled to a collector terminal of the first output transistor and a second sense resistor coupled to a collector terminal of the scaled replica transistor, wherein a resistance of the first sense resistor is scaled down by the factor of M relative to a resistance of the second sense resistor.

6. The test equipment system of claim 2, wherein the control circuit comprises a differential amplifier circuit configured to sense respective voltages at each of the first output transistor and the scaled replica transistor and, in response, provide a first current signal at a base node of the sense device.

7. The test equipment system of claim 6, wherein the control circuit comprises a current mirror configured to provide the supplement current as a scaled-up version of the first current signal.

8. The test equipment system of claim 1, comprising a class A buffer stage configured to receive a DUT control signal and, in response, provide an output signal to an input node of the first output stage, wherein the first output stage comprises a class AB output stage.

9. The test equipment system of claim 8, wherein the class A buffer stage comprises a source follower circuit coupled to the bias circuit.

10. The test equipment system of claim 8, wherein the class A buffer stage and class AB output stage comprise portions of a per-pin parametric measurement unit (PPMU or PMU) of the test equipment system.

11. A compensation circuit for an output stage of a test signal driver system, the compensation circuit comprising:
a replica transistor comprising a physically scaled-down replica of a first transistor in an output stage of the pin driver system;
a control circuit configured to provide a first drive current at a base node of the replica transistor based on information about a voltage difference between the replica transistor and the first transistor in the output stage; and
a current source configured to provide a supplement current at a base node of the first transistor in the output stage, wherein the supplement current is scaled relative to the first drive current in a same ratio as the first transistor in the output stage is physically scaled relative to the replica transistor.

12. The compensation circuit of claim 11, wherein the first transistor comprises M parallel-coupled PNP transistors and the replica transistor comprises at least one but fewer than M PNP transistors.

13. The compensation circuit of claim 12, wherein the control circuit comprises a differential amplifier configured to receive respective voltage signals from collector terminals of the replica transistor and the first transistor in the output stage; and
wherein the current source comprises a current mirror circuit.

14. A method for operating an automated test equipment (ATE) system, the method comprising:
sensing a magnitude of a first current at a device under test (DUT) interface of a DUT driver output stage;
generating a supplement current based on the sensed magnitude of the first current;
providing the supplement current at a base node of an output transistor in the output stage.

15. The method of claim 14, wherein the output stage of the ATE system comprises an output stage with a first NPN transistor coupled to a first PNP transistor, and wherein sensing the magnitude of the first current includes using a second PNP transistor that is a scaled replica of the first PNP transistor.

16. The method of claim 15, comprising:
receiving information about a first collector voltage of the first PNP transistor;
receiving information about a second collector voltage of the second PNP transistor;
using a bias control circuit, providing the supplement current to the base node of the first PNP transistor and providing a second bias current to a base node of the second PNP transistor to equalize the first and second collector voltages.

17. The method of claim 16, comprising providing the second bias current to a current mirror circuit and generating the supplement current as a scaled-up version of the second bias current using the current mirror circuit.

18. The method of claim 14, comprising biasing the output transistor in the output stage and biasing a buffer circuit using a first current source, wherein an output of the buffer circuit is coupled to an input of the output stage.

19. The method of claim 14, comprising using a feedback network to equalize current density characteristics of the output transistor and a sense transistor;
wherein sensing the magnitude of the first current includes using the sense transistor, and the sense transistor is a scaled replica of the output transistor.

20. The method of claim 14, comprising:
sensing a change in magnitude of the first current at the DUT interface of the output stage;
generating an updated supplement current based on the sensed change in magnitude of the first current; and
providing the updated supplement current at the base node of an output transistor in the output stage.
